(19) United States
(12) Patent Application Publication
(10) Pub. No.: US 2001/0023522 A1
(43) Pub. Date: Sep. 27, 2001

(54) Flexibly interconnected vacuum chambers comprising load-canceling device therebetween, and process apparatus comprising same

(76) Inventors: Douglas C. Watson, Campbell, CA (US); Hidekazu Kikuchi, Miyagi-ken (JP)

Correspondence Address: KLARQUIST SPARKMAN CAMPBELL LEIGH & WHINSTON, LLP, One World Trade Center, Suite 1600, 121 S.W. Salmon Street, Portland, OR, 97204-2988, US

(21) Appl. No.: 09/769,559

(22) Filed: Jan. 24, 2001

(30) Foreign Application Priority Data
Jan. 25, 2000 (JP) 2000-015738

(51) Int. Cl. H01L 21/00; H01L 21/64

(52) U.S. Cl. 29/25.01

(57) ABSTRACT

Load-canceling devices are disclosed that cancel axial compressive forces acting on a pass-through flexible conduit interconnecting neighboring vacuum chambers. The load-canceling devices also prevent vibrations occurring in one vacuum chamber from being transmitted to the other vacuum chamber. The load-canceling devices can be configured with any of various configurations such as air springs or any of various vacuum-bellows mechanisms. The load-canceling devices desirably are situated on opposite sides of the pass-through flexible conduit, thereby providing counter-forces, to the axial compressive force, having directions parallel to the direction of the axial compressive force. The load-canceling devices can be sized such that the cumulative counter-force generated by them is equal but exactly opposite in direction to the axial compressive force, thereby eliminating the axial compressive force.

### FIELD OF THE INVENTION

This invention pertains to microelectronic-processing apparatus and methods in which a respective process is performed in a subatmospheric pressure (“vacuum”). A principal example of such an apparatus is any of various microlithographic exposure apparatus, especially such apparatus employing a charged particle beam as a microlithography energy beam. More specifically, in the context of such apparatus and methods, the invention pertains to pass-through flexible conduits between separate vacuum chambers, such as between a process vacuum chamber (in which actual microlithographic exposure of a wafer occurs) and a conveyor vacuum chamber (containing a robotic conveyor or the like for transporting wafers to and from the exposure chamber and another chamber such as a load-lock chamber). Even more specifically, the invention pertains, inter alia, to “load-canceling” devices adapted to extend between adjacent flexibly interconnected vacuum chambers and configured to eliminate or at least substantially reduce axial compressive forces otherwise impinging on the respective pass-through flexible conduit interconnecting the vacuum chambers. In other words, the load-canceling devices tend to reduce forces otherwise urging the chambers together.

### BACKGROUND OF THE INVENTION

Various microelectronic-fabrication processes must be conducted in a subatmospheric (“vacuum”) environment to reduce or eliminate adverse effects of atmospheric gases and pressure as the respective processes are being conducted. For example, charged-particle-beam (CPB) microlithography (i.e., microlithographic exposure of a semiconductor wafer using a charged particle beam such as an electron beam or ion beam) must be performed in a vacuum environment for reasons similar to those requiring that electron microscopy be performed in a vacuum environment. Typically, in any of such various apparatus, a “process” vacuum chamber encloses the wafer as the wafer is undergoing the respective process. The process vacuum chamber usually is connected to a separate “conveyor” vacuum chamber that contains the mechanism (usually robotic) for conveying wafers to and from the process vacuum chamber. Each vacuum chamber is evacuated by a separate vacuum pump. The interconnection between the vacuum chambers is a “pass-through” type, by which is meant that the interconnection defines an inter-chamber passageway through which wafers are conveyed from one vacuum chamber to the other.

As a specific example, reference is made to a conventional CPB microlithography apparatus, in which the exposure components are contained within a process vacuum chamber. Exemplary exposure components contained with the process vacuum chamber include the illumination-optical system, the reticle stage, the projection-optical system, and the wafer stage. A conveyor mechanism that supplies and transports fresh wafers into the process vacuum chamber and removes exposed wafers from the process vacuum chamber is contained within a separate conveyor vacuum chamber. To allow new wafers being conveyed through the conveyor vacuum chamber to enter and leave the process vacuum chamber, a pass-through conduit interconnects the two vacuum chambers.

Two respective configurations of pass-through conduits of conventional CPB microlithography apparatus are shown in FIGS. 9 and 10. Turning first to FIG. 9, the configuration is a rigid, direct pass-through port between the process vacuum chamber 3 and the conveyor vacuum chamber 4. The process vacuum chamber 3 contains a wafer stage 8 and is in communication with a column P containing the projection-optical system, a reticle-stage chamber R, and a column I containing the illumination-optical system. The conveyor vacuum chamber 4 contains a conveyor robot 7 situated and configured to transport individual fresh wafers 5 from an adjacent load-lock chamber 14 through the conveyor vacuum chamber 4 to the process vacuum chamber 3, and to transport exposed wafers in a reverse manner. The load-lock chamber 14, the conveyor vacuum chamber 4, and the process vacuum chamber 3 are each evacuated as required by a respective vacuum pump 15, 10, 11. The load-lock chamber 14 is connected to the conveyor vacuum chamber 4 via an interconnect gate valve 9, and is configured to receive wafers from the outside through an access gate valve 16.

The process vacuum chamber 3 is mounted to a rigid base 12 via vibration dampers or isolators 6, which typically have low stiffness and serve to reduce transmission of external vibrations (e.g., vibrations transmitted upward from floor level F.L. to the components located within the process vacuum chamber 3). The attainment of satisfactory inhibition of vibration transmission from use of the vibration dampers 6 requires that highly accurate positioning technology be utilized for the vibration dampers 6. Microlithography apparatus are highly susceptible to external disturbances. Consequently, the vibration dampers 6 conventionally are configured to perform both passive vibration damping (e.g., via use of air springs) and active vibration damping (e.g., via use of voice-coil motors or “VCMs”).

As can be seen in FIG. 9, the conveyor vacuum chamber 4 is connected rigidly to and extends from the process vacuum chamber 3. Consequently, vibrations from the load-lock chamber 14, the vacuum pump 10, and the conveyor robot 7 are transmitted without any significant damping or attenuation to the process vacuum chamber 3 and hence to the wafer stage 8. Whenever highly accurate positioning of the wafer 5, mounted on the wafer stage 8 in the process vacuum chamber 3, is required in preparation for and during exposure, the conveyor robot 7 cannot be operating. In other words, conveying of wafers 5 cannot be performed in parallel with performing microlithographic exposures. Rather, wafer conveying and exposure must be executed serially and separately, which has a substantial adverse effect on throughput.

Turning now to FIG. 10, the pass-through configuration is a flexible passthrough conduit between the process vacuum chamber 3 and the conveyor vacuum chamber 4. The process vacuum chamber 3 is mounted to the base 12 similarly as in the FIG. 9 configuration. The conveyor vacuum chamber 3 is mounted separately to the base 12, and is connected to the process vacuum chamber 4 via the pass-though conduit configured as a pass-through bellows 1. The pass-through bellows 1, being flexible, purportedly reduces transmission of vibrations from the conveyor vacuum chamber 4 to the process vacuum chamber 3. Other components shown in FIG. 10 that are the same as respective components shown in FIG. 9 have the same respective reference numerals and are not described further.

In FIG. 10, the pressure inside the process vacuum chamber 3 is denoted P3, the pressure inside the pass-through bellows 1 is denoted P2, and the pressure inside the conveyor vacuum chamber 4 is denoted P1. Normally, these pressures are related to each other by: P1>P2>P3. But, since these three spaces are contiguous with each other, these three pressures can be identical.

Whenever the space inside the pass-through bellows 1 is under vacuum, the pass-through bellows 1 is subject to an “axial” compressive force. By “axial” is meant that the compressive force has a direction parallel to a central axis passing horizontally (in the figure) through the pass-through bellows 1 from the process vacuum chamber 3 to the conveyor vacuum chamber 4. The axial compressive force is proportional to the effective surface area of a transverse section of the pass-through bellows 1 and to differences in pressure between the outside atmospheric pressure and the vacuum inside the pass-through bellows. For example, an exemplary bellows sufficiently large to pass a 300-mm diameter wafer 5 has a transverse section measuring 50 mm×336 mm. The total axial compressive force (applied from both directions along the axis) on such a bellows is approximately 3400 N. Even though the process vacuum chamber 3 is mounted to the base 12 with active vibration damping, the pass-through bellows 1 cannot withstand such an axial compressive force easily. Furthermore, the large axial compressive force experienced by the pass-through bellows 1 causes a substantially increased current flow to the VCMs of the vibration dampers 6. The resulting heating of the VCMs reduces their effectiveness.

To reduce the axial compressive force applied to the pass-through bellows 1, the FIG. 10 configuration includes bars 20, placed external to the pass-through bellows 1 and extending between the process vacuum chamber 3 and the conveyor vacuum chamber 4. Because the bars 20 essentially form a rigid connection between the process vacuum chamber 3 and the conveyor vacuum chamber 4, vibrations from the conveyor vacuum chamber 4 (e.g., from the vacuum pump 10 and conveyor robot 7) are transmitted without any substantial attenuation (despite the pass-through bellows 1) to the process vacuum chamber 3. As a result, there is no choice but to conduct exposures of the wafers 5 at times that are separate from times during which wafers are being conveyed. The consequential need to perform wafer transport and wafer exposure at different times in a series manner reduces throughput of the CPB microlithography.

### SUMMARY OF THE INVENTION

In view of the disadvantages of conventional apparatus and methods as summarized above, an object of the invention is to provide, for a flexible interconnection between, e.g., a process vacuum chamber and a conveyor vacuum chamber, at least one load-canceling device that “cancels” (at least substantially reduces or effectively eliminates) axial compressive forces impinging on the flexible interconnection. Another object is to provide such a load-canceling device that prevents or reduces vibrations emanating from one vacuum chamber from being transmitted to the other vacuum chamber connected thereto via a flexible interconnection.

To such ends and according to a first aspect of the invention, devices are provided for reducing an axial compressive force experienced by a pass-through flexible conduit (e.g., bellows conduit) connecting together a first and a second vacuum chamber (as used, e.g., in the context of a processing apparatus). The pass-through flexible conduit has an axis extending from the first vacuum chamber to the second vacuum chamber and is subjected to an axial compressive force whenever the vacuum chambers are evacuated relative to an environment surrounding the vacuum chambers. An embodiment of the device for reducing the axial compressive force comprises a load-canceling device that flanks the pass-through flexible conduit. The load-canceling device comprises a first end connected to the first vacuum chamber and a second end connected to the second vacuum chamber. The load-canceling device is configured to apply a counter-force serving to offset and cancel at least a portion of the axial compressive force.

Desirably, the pass-through flexible conduit is flanked by multiple load-canceling devices. For example, a first load-canceling device can be situated on a first axial side of the pass-through flexible conduit and a second load-canceling device can be situated on a second axial side, opposite the first axial side, of the pass-through flexible conduit.

As noted above, whenever a bellows or analogous pass-through flexible conduit is used to connect two vacuum chambers, an axial compressive force acts upon the pass-through bellows whenever the pressure inside the pass-through bellows (and vacuum chambers) is substantially less than the pressure outside the pass-through bellows. The load-canceling device connected between the vacuum chambers serves to “cancel” (substantially reduce or offset) the axial compressive force.

The load-canceling device desirably has low stiffness (at least lower than the stiffness of a rigid rod). The load-canceling device can be configured as an air spring, vacuum-bellows mechanism, elastic or compliant mass, or analogous structure. A load-canceling device does not readily transmit vibration emanating in one vacuum chamber to the other vacuum chamber. As a result of canceling the axial compressive force and attenuating transmission of vibrations from one vacuum chamber to the other, it now is possible to perform substrate conveyance (within one vacuum chamber) and substrate processing (within the other vacuum chamber) simultaneously (i.e., in parallel) rather than in series. Hence, process throughput is increased relative to the throughput realized using conventional apparatus.

A representative load-canceling device is an air spring. Among various load-canceling devices, air springs have relatively low stiffness, and hence exhibit good vibration attenuation. Also, with an air spring, it is possible to achieve good load-canceling performance, even with a small surface area of contact of the air spring with a respective chamber, simply by increasing the air pressure within the air spring. Hence, using an air spring, it is possible to achieve good vibration attenuation without requiring excessive size or mass.

Certain load-canceling devices such as air springs effectively attenuate vibration propagating along the axis of the load-canceling device, but have limited vibration-attenuating ability in other directions and limited ability to attenuate bending displacements. Especially in such instances, the load-canceling device can be connected at least to one of the vacuum chambers via a “displacement absorber” or flexible joint. The displacement absorber desirably is configured to absorb pitch, roll, and yaw of one vacuum chamber relative to the other vacuum chamber. The displacement absorber desirably also is configured to absorb displacements of one vacuum chamber relative to the other vacuum chamber in two dimensions perpendicular to the axis of the pass-through flexible conduit. A particularly effective displacement absorber is mounted on the load-transmission element of the load-canceling device and is configured to absorb displacements in the remaining five cardinal directions. Hence, it is especially difficult for vibrations propagating in any direction to be transmitted from one vacuum chamber to the other.

In one possible configuration, the displacement absorber comprises a cross-roller table assembly attached to the first vacuum chamber, a socket block attached to the cross-roller table assembly, and a spherical bearing member. The spherical bearing member has a first end configured as a spherical bearing journaled in the socket block, and a second end connected to the load-canceling device. Alternatively, the cross-roller table can be eliminated by incorporating, for example, a respective spherical bearing at each end of the load-canceling device.

Another embodiment of a load-canceling device comprises a vacuum-bellows mechanism having a first end connected to the first vacuum chamber and a second end connected to the second vacuum chamber. The vacuum-bellows mechanism is configured to generate the counter-force based on a pressure differential between a vacuum level established in at least one of the first and second vacuum chambers and the environment surrounding the first and second vacuum chambers. Desirably, the vacuum-bellows mechanism is connected via a conduit to at least one of the first and second vacuum chambers. The conduit provides a pressure in the vacuum bellows that is substantially equal to a pressure in the at least one vacuum chamber to which the conduit is connected. Thus, the counter-force is adjusted automatically whenever the pressure in the vacuum chamber(s) (to which the conduit is connected) fluctuates.

In another embodiment, a first support member is connected to the first vacuum chamber and includes a respective free end extending from the first vacuum chamber. Also, a second support member is connected to the second vacuum chamber and includes a respective free end extending from the second vacuum chamber. In this configuration, the vacuum bellows connects together the free ends of the first and second support members. The vacuum bellows is oriented so as to generate, whenever the first and second vacuum chambers are evacuated, an axial counter-force having a direction opposite the direction of the axial compressive force. In other words, whenever the vacuum bellows contracts due to a lower pressure inside the bellows compared to outside the bellows, the resulting counter-force that is generated by the vacuum bellows acts to urge the vacuum chambers to move apart, thereby canceling the axial compressive force. If multiple such load-canceling devices are provided, the sum of the transverse sectional areas of the multiple bellows desirably is equal to the transverse sectional area of the pass-through flexible conduit so as to eliminate the axial compressive force. This elimination of the axial compressive force can be self-adjusting, in the manner described above, with fluctuations in the pressure in the vacuum chambers. This type of load-canceling device also is capable of absorbing, at least to a limited extent, displacements in the six cardinal directions.

In yet another embodiment, each load-canceling device can comprise a first respective vacuum bellows connected to the first vacuum chamber, and a respective chamber connected to the first respective vacuum bellows and to the second vacuum chamber, wherein the respective chamber has an interior surface defining a respective interior space. Each load-canceling means also includes a second respective vacuum bellows connected to the interior surface and situated in the respective interior space. A piston plate is located in the interior space, connected to the second respective vacuum bellows. The first respective vacuum bellows is configured to provide a fluid connection from the first vacuum chamber to a space bounded by the interior surface, an inside surface of the second respective vacuum bellows, and the piston plate. The piston plate is connected to the first vacuum chamber. In this configuration, if the transverse section of the first vacuum bellows has an area A₁, the chamber has a transverse section with area A₂, and atmospheric pressure is denoted Pₐ, then an axial compression force of only Pₐ·A₁ is exerted between the first vacuum chamber and the chamber. This force tends to pull the second vacuum chamber toward the first vacuum chamber. Also, a counter-force of Pₐ·A₂ is exerted on the piston plate from the first vacuum chamber; this force, acting on the chamber, tends to urge the second vacuum chamber to move away from the first vacuum chamber. Hence, a net counter-force of Pₐ(A₂−A₁) is exerted between the first vacuum chamber and the second vacuum chamber. If multiple such load-canceling devices are situated between the first and second vacuum chambers (desirably symmetrically flanking the pass-through flexible conduit), then the sum of their counter-forces can be made equal to the axial compressive force, thereby eliminating the axial compressive force.

By using multiple load-canceling devices symmetrically flanking the pass-through flexible conduit, the counter-force can be applied in the axial direction without any significant components in directions other than axial. Hence, the axial compression force can be canceled without any off-axis displacement.

According to another aspect of the invention, vacuum-chamber assemblies are provided. An embodiment of such an assembly comprises a first vacuum chamber, a second vacuum chamber, and a pass-through flexible conduit as summarized above. The embodiment also comprises multiple load-canceling devices extending between the first and second vacuum chambers. The load-canceling devices desirably flank the pass-through flexible conduit such that the load-canceling devices are situated axially symmetrically relative to the pass-through flexible conduit. Each load-canceling device is configured to apply a counter-force serving to offset a respective share of the axial compressive force. In an especially desirable configuration, two load-canceling devices are situated symmetrically on opposite sides of the pass-through flexible conduit. This configuration of two load-canceling devices minimizes the area, on each of the vacuum chambers, to which the load-canceling devices are attached, thereby allowing the capacity of the vacuum chambers to be minimized as required. Desirably, the load-canceling devices extend horizontally to allow the major dimensions of the vacuum chambers to extend horizontally (which is a better configuration for accommodating conveyor robots, etc.).

According to another aspect of the invention, microlithography apparatus are provided that comprise an exposure-beam-optical column, first and second vacuum chambers, a pass-through flexible conduit connecting together the vacuum chambers, and a load-canceling device flanking the pass-through flexible conduit. The first vacuum chamber includes a first portion enclosing at least a portion of the exposure-beam column and a second portion enclosing a substrate stage. The second vacuum chamber encloses a conveyor for transporting substrates to and from the substrate stage. The load-canceling device comprises a first end connected to the first vacuum chamber and a second end connected to the second vacuum chamber, and is configured to apply a counter-force serving to offset and cancel at least a portion of the axial compressive force. Thus, vibrations in the first vacuum chamber are not transmitted to the second vacuum chamber, allowing conveyance and exposure operations to be conducted in parallel, yielding good throughput.

The foregoing and additional features and advantages of the invention will be more readily apparent from the following detailed description, which proceeds with reference to the accompanying drawings.

### BRIEF DESCRIPTION OF THE DRAWINGS

FIG. 1 is a schematic plan-sectional view of a first representative embodiment of the invention, including multiple air springs (as representative load-canceling devices) flanking a pass-through bellows situated between a process vacuum chamber and a conveyor vacuum chamber.

FIG. 2 is an elevational-sectional view of the embodiment shown in FIG. 1.

FIG. 3 is an oblique view of a displacement absorber as used in the embodiment of FIGS. 1 and 2.

FIG. 4 is a schematic plan-sectional view of a second representative embodiment of the invention, including multiple vacuum-bellows mechanisms flanking the pass-through bellows situated between the process vacuum chamber and the conveyor vacuum chamber.

FIG. 5 is a schematic plan-sectional view of a third representative embodiment of the invention, including multiple alternative configurations of vacuum-bellows mechanisms situated between the process vacuum chamber 3 and the conveyor vacuum chamber.

FIG. 6 is a schematic optical diagram of a charged-particle-beam microlithography apparatus according to the fourth representative embodiment.

FIG. 7 is a process flowchart for manufacturing a microelectronic device, wherein the process includes a microlithography method according to the invention.

FIG. 8 is a process flowchart for performing a microlithography method that includes a projection-exposure method according to the invention.

FIG. 9 is a schematic elevational view of a configuration, in the context of a microlithography apparatus, of a conventional rigid interconnection between a process vacuum chamber and a conveyor vacuum chamber.

FIG. 10 is a schematic elevational view of a configuration, in the context of a microlithography apparatus, of a conventional pass-through bellows interconnection between a process vacuum chamber and a conveyor vacuum chamber.

### DETAILED DESCRIPTION

This invention is described below in the context of multiple representative embodiments that are intended to be exemplary of various configurations within the scope of the invention. It will be understood that the representative embodiments are not intended to be limiting in any way.

First Representative Embodiment

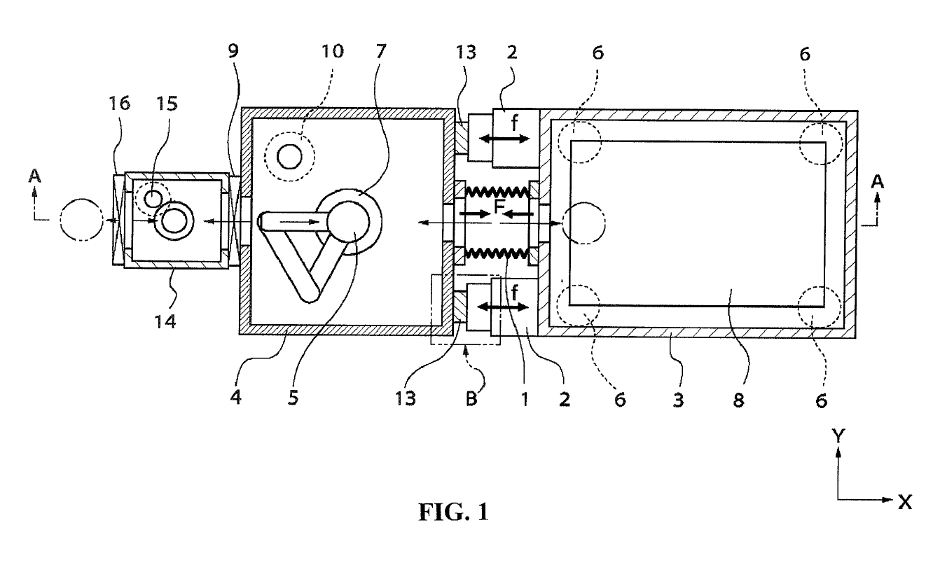

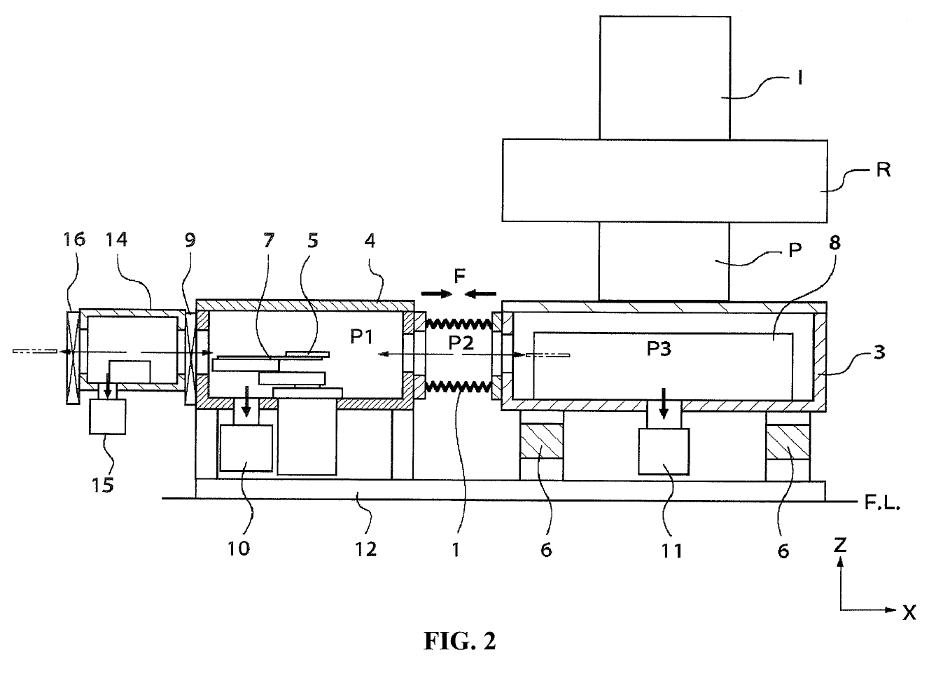

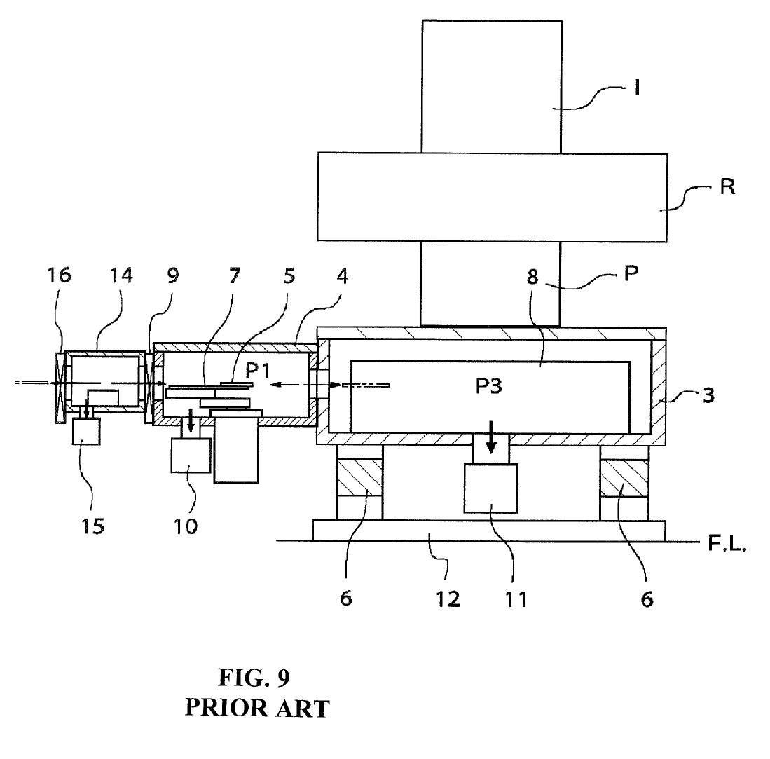

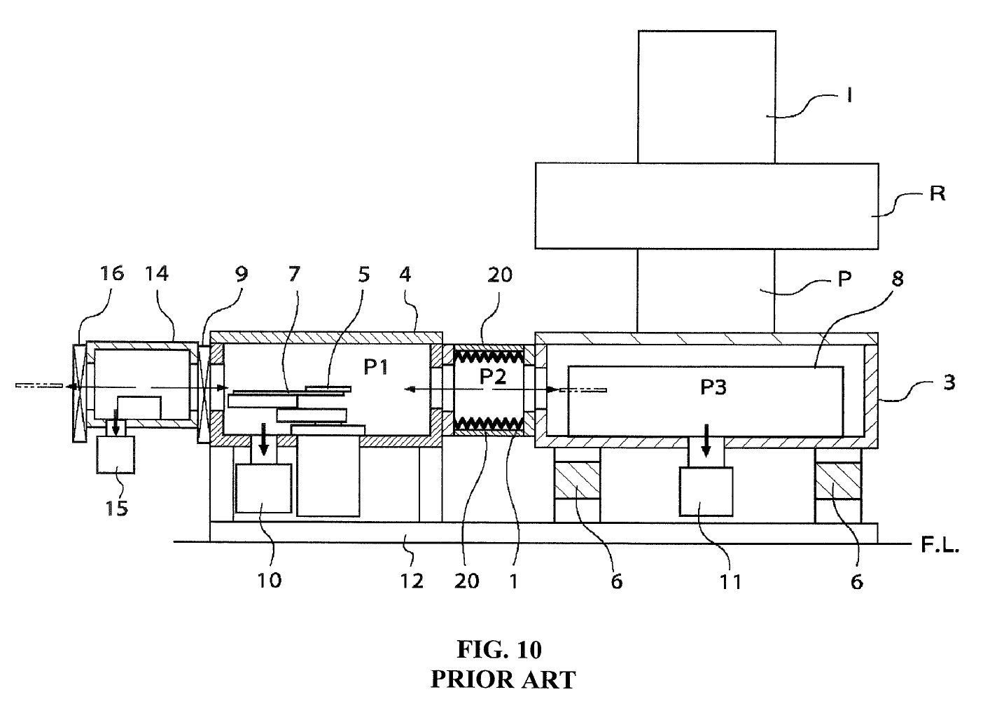

This embodiment is depicted in FIGS. 1 and 2 in the context of a microlithography apparatus. FIG. 1 is a sectional plan view of the several vacuum chambers of this embodiment, and FIG. 2 is an elevational section along the line A-A in FIG. 1. In FIGS. 1 and 2, components that are the same as respective components shown in FIGS. 9 and 10 have the same respective reference numerals. These components include a pass-through bellows 1, a process vacuum chamber 3, a conveyor vacuum chamber 4, vibration dampers 6, a conveyor robot 7, a wafer stage 8, an interconnect gate valve 9, vacuum pumps 10, 11, a base 12, a load-lock chamber 14, a vacuum pump 15, and an access gate valve 16. The pass-through bellows 1 (as a representative flexible pass-through conduit) connects the process vacuum chamber 3 to the conveyor vacuum chamber 4. The process vacuum chamber 3 is mounted to the base 12 via the vibration dampers 6. The conveyor vacuum chamber 4 is mounted to the base separately of the process vacuum chamber 3.

The sequence of events by which a wafer 5 is conveyed from outside the access gate valve 16 to inside the process vacuum chamber 3 is as follows. The pressure in the load-lock chamber 14 is brought to atmospheric pressure. The access gate valve 16 opens, and a wafer 5 is conveyed by an external robot (not shown) into the load lock chamber 14. The access gate valve 16 is closed, and evacuation of the load-lock chamber 14 commences by operation of the vacuum pump 15. After the load-lock chamber 14 has been evacuated to a pre-specified target vacuum (usually equal to the vacuum level in the conveyor vacuum chamber 4), the interconnect gate valve 9 opens. The conveyor robot 7 picks up the wafer 5 from the load-lock chamber 14 and conveys the wafer 5 into the conveyor vacuum chamber 4. The interconnect gate valve 9 closes, and the conveyor robot 7 delivers the wafer 5 through the pass-through bellows 1 into the process vacuum chamber 3. The conveyor robot 7 places the wafer 5 on the wafer stage 8 for exposure. After exposure is complete, the foregoing sequence is reversed to remove the wafer 5 from the process vacuum chamber 3, through the pass-through bellows 1 and conveyor vacuum chamber 4, and through the load-lock chamber 14.

The pass-through bellows 1 (in the nature of conventional bellows) has a fluted configuration. The flutes desirably are configured in the manner of a coil spring to provide the pass-through bellows 1 with axial flexibility, lateral flexibility, and radial strength. The axial flexibility allows some bending and hence some lateral flexibility between ends. The degree of flexibility depends upon the length of the pass-through bellows 1. As can be ascertained from the above, the pass-through bellows 1 defines an interior space and thus serves as a conduit through which wafers can be “passed through” (transported axially from the conveyor vacuum chamber 4 to the process vacuum chamber 3, and vice versa). Characteristic of a conduit connecting the vacuum chambers 3, 4, the interior space defined by the pass-through bellows 1 is evacuated to a suitable vacuum along with the vacuum chambers. Evacuation of the interior space of the pass-through bellows 1 in this manner subjects the pass-through bellows 1 to a large axial compressive force (arrows F in FIG. 1).

In accordance with the invention, this embodiment includes at least one “load-canceling device” that flanks the pass-through bellows 1 and that is connected both to the process vacuum chamber 3 and the conveyor vacuum chamber. The load-canceling device serves to apply a counter-force that offsets and cancels at least a portion of the axial compressive force. The counter-force in this embodiment is opposite in direction to the axial compressive force. This embodiment specifically comprises multiple load-canceling devices configured as respective air springs 2. The air springs 2 extend between the process vacuum chamber 3 and the conveyor vacuum chamber 4, and flank the pass-through bellows 1. Each air spring 2 can be mounted to the conveyor vacuum chamber 4 via a respective displacement absorber 13, described later below. Desirably, two air springs 2 are employed at the same elevation (in the Z-direction) but flanking the pass-through bellows 1. (In this context, “flanking” the pass-through bellows 1 means spaced equidistantly on opposite sides (in the Y-direction) of the pass-through bellows 1.) Each air spring 2 can exhibit axial displacement due to an axially compressive force (see above) applied by the pass-through bellows 1. Each air spring 2 applies a respective force “f” (note arrows), counter-directional to the force F. With two air springs 2, each force f desirably is equal to F/2. In such a condition, the forces f collectively applied by the air springs 2 cancel the force F and thus cancel the “load” (i.e., axial compressive force) on the pass-through bellows 1.

The air springs 2 also attenuate transmission of vibration from the conveyor vacuum chamber 4 to the process vacuum chamber 3. The transmissivity of the vibration is a function of the stiffness of the air springs 2 and the pass-through bellows 1, and of the respective masses of the two vacuum chambers 3, 4. Hence, the air springs 2 greatly reduce (to at most a very small residual level) the magnitude of vibration transmitted to the process vacuum chamber 3 from the conveyor vacuum chamber 4, the vacuum pumps 10, 15, the conveyor robot 7, and the gate valves 9, 16. Also, the passthrough bellows 1 itself contributes to reducing transmission of vibration between the vacuum chambers 3, 4.

According to the foregoing, vibrations generated by and during transportation of the wafer 5 to and from the wafer stage 8 are not transmitted to the process vacuum chamber 3 and hence not to the wafer stage 8. As a result, it now is possible to transport the next wafer 5 from the outside and convey it into the conveyor vacuum chamber 4 as a current wafer is being exposed in the process vacuum chamber 3. (The conveyor vacuum chamber 4 can be provided with a “wait table” (not shown) on which the next wafer is placed after being transported into the vacuum chamber 3 during exposure of the current wafer. For conveying the next wafer from the wait table to the wafer stage 8 after completing exposure of the current wafer, the conveyor robot 7 can have a double-arm configuration.) In other words, wafer exposure and wafer transport can be conducted in parallel, which provides a corresponding substantial improvement in throughput.

In an alternative configuration, three or more air springs 2 can be used. In such a configuration, the air springs 2 desirably are situated equidistantly from the axis of the pass-through bellows 1 and equi-angularly with respect to each other. Each air spring 2 cancels its respective share of the force F; thus, the air springs 2 collectively cancel substantially the entire axial compressive force F impinging on the pass-through bellows 1.

Whereas the air springs 2 are especially suitable for attenuating vibration in the manner described above, it alternatively is possible (depending upon the circumstances) to employ mechanical springs or analogous appliance made of springy, elastic, or compliant material to attenuate the vibration.

The vibration dampers 6 are situated between the process vacuum chamber 3 and the base 12. The vibration dampers 6 desirably perform both active and passive vibration damping. The vibration dampers 6 attenuate transmission of vibration from the base 12 to the process vacuum chamber 3 and dampen at least some motions of the process unit comprising the process vacuum chamber 3 and superstructure mounted to it such as the columns P, I and reticle chamber R. Whereas the vibration dampers 6 are effective for control of most of these vibrations and motions, situations can arise in which inertia, mass shifts, or accelerations of the structure supported by the vibration dampers 6 are substantial. Under these unusual conditions, the vibration dampers 6 require significant time to compensate for the vibrations and movements, which can result in forward/backward bending or twisting movements of the structure that cause unplanned motions of the wafer stage 8.

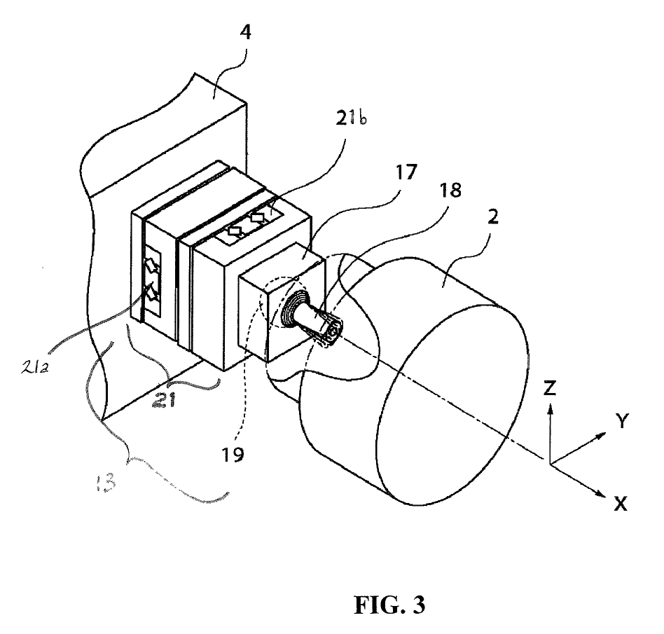

To prevent the effects of these additional vibrations and motions, this embodiment comprises the displacement absorbers 13 connecting the air springs 2 to the conveyor vacuum chamber 4. The displacement absorbers 13 are configured to prevent transmission of certain vibrations and other motions from the conveyor vacuum chamber 4 to the respective air springs 2. An exemplary configuration of a displacement absorber 13 is detailed in FIG. 3, which depicts in detail the region denoted “B” in FIG. 1. In FIG. 3, components that are the same as respective components shown in FIGS. 1 and 2 have the same respective reference numerals. The displacement absorber 13 shown in FIG. 3 includes a socket block 17, a shaft 18 connected to the respective air spring 2, and a spherical bearing 19 connecting the shaft 18 to the socket block 17. Relative to the socket block 17, the spherical bearing 19 permits the shaft 18 to move as indicated in the figure. The displacement absorber 13 also comprises a cross-roller table assembly 21 connecting the socket block 17 to the conveyor vacuum chamber 4. The cross-roller table assembly 21 includes a Y-direction cross-roller table 21a and a Z-direction cross-roller table 21b.

As noted above, the air springs 2 are effective for absorbing displacements in the X-direction (axial direction of the pass-through bellows 1). However, the air springs 2 are relatively ineffective for absorbing pitch, roll, or yaw and for absorbing displacements in the Y-direction or Z-direction. In the configuration shown in FIG. 3, the air springs 2 are connected to respective displacement absorbers 13 that compensate for these limitations of the air springs.

As noted above, the socket blocks 17 are connected to the conveyor vacuum chamber 4 via respective cross-roller table assemblies 21. Because each cross-roller table assembly 21 comprises a respective Y-direction cross-roller table 21a and a respective Z-direction cross-roller table 21b, each displacement absorber 13 can absorb displacements in the Y- and Z-directions.

As noted above, air springs have a stiffness. The stiffness of an air spring depends upon, inter alia, the air volume and piston area inside the air spring, and the pressure inside the air spring. Hence, the stiffness can be adjusted or changed by changing the pressure inside the air spring. Changing the air pressure inside the air spring also adjusts the compression and/or extension of the air spring where desired. Also, air springs compress under load, which can cause relative displacement of the vacuum chambers 3, 4. The relative displacement is subject to change with changes in atmospheric pressure. This phenomenon can be compensated for by, for example, active control of air pressure, which would require positional feedback, pressure feedback, and active-control electronics.

By connecting the process vacuum chamber 3 to the conveyor vacuum chamber 4 in the manner according to this embodiment, transmission of displacements of the conveyor vacuum chamber 4 in any of the six axial directions to the process vacuum chamber 3 is attenuated.

Second Representative Embodiment

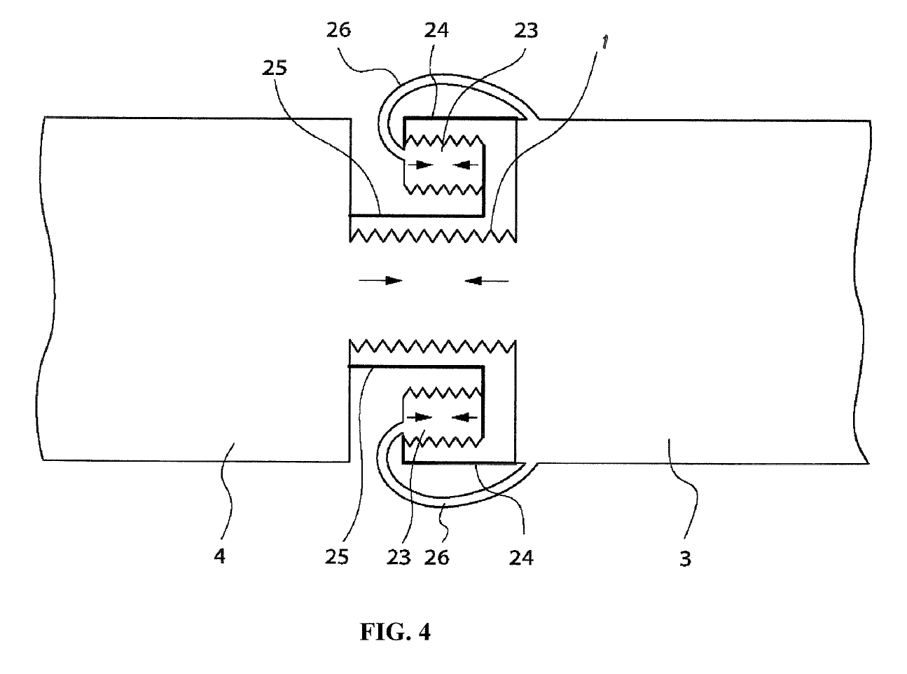

This embodiment is shown in FIG. 4. This embodiment differs from the first representative embodiment by utilizing “vacuum-bellows mechanisms” in place of the air springs 2. The vacuum-bellows mechanisms exploit the vacuum established in the vacuum chambers 3, 4 to cancel the axial compressive force on the pass-through bellows 1.

This embodiment is identical to the first representative embodiment except for the particular configuration of the load-canceling device situated between the process vacuum chamber 3 and the conveyor vacuum chamber 4. Because the differences between the two embodiments are in the region between the vacuum chambers 3, 4, only this region is depicted in FIG. 4.

In FIG. 4, the process vacuum chamber 3 is connected to the conveyor vacuum chamber 4 via a pass-through bellows 1 as described above. The pass-through bellows 1 is flanked by vacuum-bellows mechanisms. Each vacuum-bellows mechanism comprises a first support member 24 mounted to the process vacuum chamber 3, a second support member 25 mounted to the conveyor vacuum chamber 4, a vacuum bellows 23 connecting the first support member 24 to the second support member 25, and a conduit 26 connecting the process vacuum chamber with the interior space defined by the vacuum bellows 23. Thus, the conduit 26 equilibrates the pressure inside the process vacuum chamber 3 with the pressure inside the vacuum bellows 23.

As described above in the first representative embodiment, the pass-through bellows 1 experiences an axial compressive force (arrows inside the bellows 1) as a result of the vacuum environment inside the vacuum chambers 3, 4 relative to outside these chambers. The axial compressive force acting on the pass-through bellows 1 alone would cause the first support member 24 to move leftward in the figure and the second support member 25 to move rightward in the figure. I.e., the axial compressive force acting on the pass-through bellows 1 alone tends to cause the vacuum chambers 3, 4 to move toward each other. But, each vacuum bellows 23 is subject to an axial compressive force (arrows inside the bellows 23) as a result of a lower pressure inside the vacuum bellows 23 than outside the vacuum bellows 23. The axial compressive forces acting on the vacuum bellows 23 alone would cause the first support member 24 to move rightward in the figure and the second support member 25 to move leftward in the figure. I.e., the axial compressive forces acting on the vacuum bellows 23 alone tend to cause the vacuum chambers 3, 4 to move away from each other. Hence, the axial compressive force collectively acting on the vacuum bellows 23 offsets the axial compressive force acting on the pass-through bellows 1. By making the collective transverse area of all the vacuum bellows 23 (i.e., transverse area of an individual vacuum bellows 23 times the number of vacuum bellows 23) substantially equal to the transverse area of the pass-through bellows 1, it is possible essentially to cancel (with the combined axial forces acting on the vacuum bellows 23) the axial compressive force acting upon the pass-through bellows 1. An advantage of this configuration is that the force cancellation is independent of atmospheric pressure changes, and the relative stiffness between the two vacuum chambers 3, 4 is determined only by the stiffness of the pass-through bellows 1.

In this embodiment, since the load-canceling devices described above collectively comprise multiple individual vacuum-bellows mechanisms, the load-canceling devices are capable (at least to a limited extent) of canceling pitch, roll, and yaw, as well as displacements in the Y-direction and Z-direction, of the vacuum chambers 3, 4 relative to each other.

Third Representative Embodiment

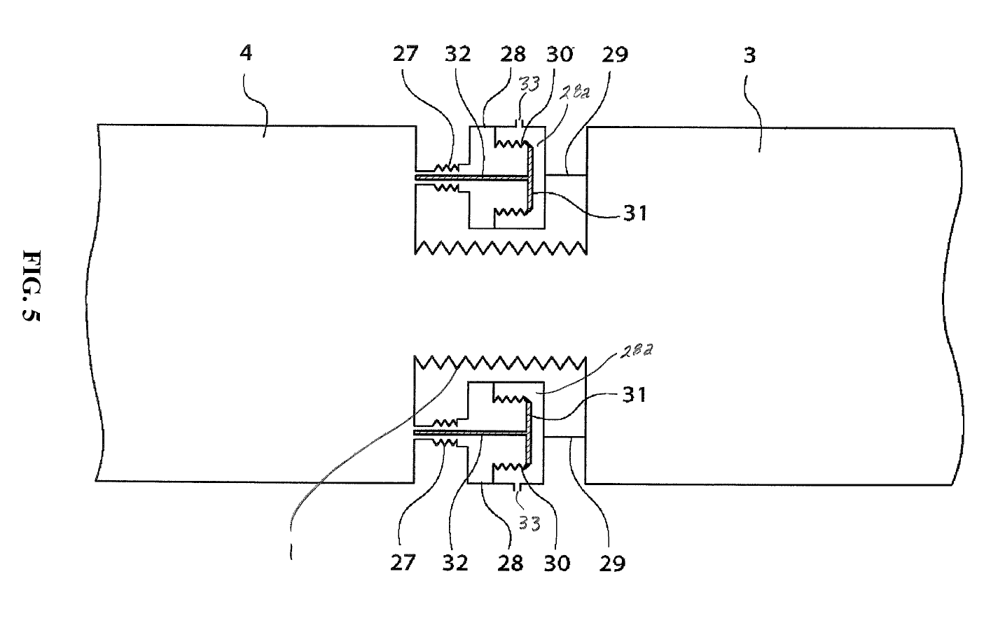

This embodiment is shown in FIG. 5. This embodiment utilizes multiple vacuum-bellows mechanisms in place of the air springs 2 used in the first representative embodiment.

As in the second representative embodiment (FIG. 4), this embodiment is configured to exploit the vacuum levels in the respective vacuum chambers 3, 4 to cancel the axial compressive force acting on the pass-through bellows 1. In FIG. 5, the process vacuum chamber 3 is connected to the conveyor vacuum chamber 4 via a pass-through bellows 1 as described above. The pass-through bellows 1 is flanked by vacuum-bellows mechanisms each comprising a first bellows 27 attached to the conveyor vacuum chamber 4, a chamber 28 (desirably cylindrical in profile) extending from the first bellows 27 and mounted via a first support member 29 to the process vacuum chamber 3, a second bellows 30 located within and attached to an inner wall of the chamber 28, a piston plate 31 attached to the second bellows 30, and a second support member 32 attached to the center of the piston plate 31. Hence, the chamber 28 is attached via the first bellows 27 to the conveyor vacuum chamber 4, and the piston plate 31 is attached via the second bellows 30 to the inner wall of the chamber 28. The portion of the chamber 28 to the right (in the figure) of the second bellows 30 defines an interior space 28a that is vented, such as by a vent port 33, to the atmosphere to allow flexing of the second bellows 30. The piston plate 31 is attached via the second support member 32 to the conveyor vacuum chamber 4. To such end, the second support member 32 can have a rod configuration. (Since FIG. 5 depicts sectional detail, the second support member 32 appears unconnected to the conveyor vacuum chamber 4; however, the second support member 32 actually is attached to the conveyor vacuum chamber 4 at a location not appearing in the drawing.)

The interior space collectively defined by respective “interior” surfaces of the first bellows 27, the chamber 28, the second bellows 30, and the piston plate 31 is contiguous with the interior space defined by the conveyor vacuum chamber 4. As noted above, the remaining interior space 28a within the chamber 28 is vented to (and thus exposed to) the atmosphere via the vent port 33.

With respect to each vacuum-bellows mechanism, if the transverse sectional area of the first bellows 27 is denoted by A₁, the transverse sectional area of the piston plate 31 is denoted by A₂, and atmospheric pressure is denoted by Pₐ, then a first compressive force of magnitude (Pₐ)·(A₁) acts between the conveyor vacuum chamber 4 and the chamber 28. The first compressive force tends to “pull” the process vacuum chamber 3 toward the conveyor vacuum chamber 4 via the first support member 29. Also, a second compressive force of magnitude (Pₐ)·(A₂) acts between the conveyor vacuum chamber 4 and the piston plate 31 via the second support member 32. The second compressive force tends to “push” the process vacuum chamber 3 from the conveyor vacuum chamber 4 via the chamber 28. The resultant net force for each vacuum-bellow mechanism is Pₐ·(A₂−A₁), acting between the process vacuum chamber 3 and the conveyor vacuum chamber 4.

Furthermore, if the number of vacuum-bellows mechanisms flanking the passthrough bellows 1 is denoted by “n”, and if n·(A₂−A₁) is made essentially equal to the transverse sectional area of the pass-through bellows 1, then the vacuum-bellows mechanisms of this embodiment are configured essentially to cancel the axial compressive force impinging on the pass-through bellows 1. In this embodiment, because the vacuum-bellows mechanisms comprise bellows configured as described above, the vacuum-bellows mechanisms are capable of canceling pitch, roll, and yaw, as well as Y-direction and Z-directions displacements of the vacuum chambers 3, 4 relative to each other.

An advantage of the second and third representative embodiments over the first representative embodiments is that, in contrast with an air spring that normally is pressurized inside, the vacuum inside the vacuum bellows has no inherent stiffness (most of the stiffness is in the external atmosphere environment). In the second and third representative embodiments, although the vacuum bellows have some residual stiffness, the stiffness is relatively low (much lower than that of an air spring) and independent of pressure. In addition, in the second and third representative embodiments, the quality of force cancellation is independent of changes in atmospheric pressure.

Another advantage of the second and third representative embodiments is that either works well at any pressure or vacuum. I.e., the second and third embodiments are not limited to being connected between vacuum chambers. These embodiments have good utility also as load-canceling devices between pressure chambers.

In any of the embodiments including a load-canceling device, one or more of the vacuum chambers can be mounted to the floor or analogous structure via low-stiffness vibration isolators.

Fourth Representative Embodiment

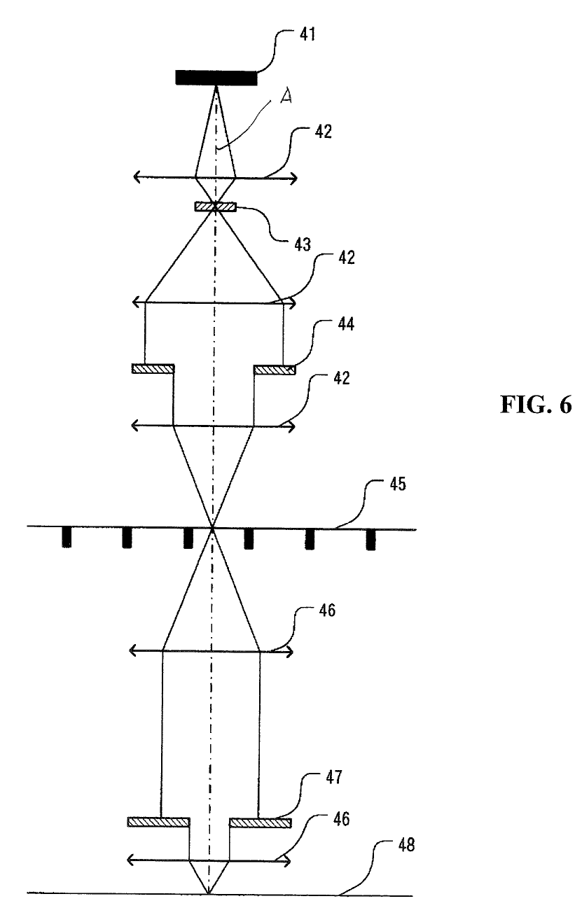

This embodiment is directed to a representative configuration of a charged-particle-beam (CPB)-optical system of a CPB microlithography apparatus. This embodiment is depicted schematically in FIG. 6. The apparatus comprises, along an optical axis A, a CPB source 41, an illumination-lens assembly 42, a hollow-beam-forming aperture 43, a first aperture stop 44, a projection-lens assembly 46, and a scattering aperture 47 (second aperture stop). The apparatus of FIG. 6 is configured to illuminate a region on a reticle 45 (defining a pattern) and to project an image of the illuminated region onto a “sensitive” substrate 48 (e.g., semiconductor wafer). By “sensitive” is meant that the upstream-facing surface of the substrate 48 is coated with a suitable exposure-sensitive material (termed a “resist”) that, when irradiated with the projected image, is capable of being imprinted with the image.

A beam of charged particles emitted from the CPB source 41 uniformly illuminates a selected region of the reticle 45 via the illumination-lens assembly 42. An image of the illuminated portion of the pattern on the reticle 45 is projected onto a corresponding region of the resist-coated substrate 48 by the projection-lens assembly 46 to imprint the region with a respective latent image of the illuminated portion. The aperture stops 44, 47 limit the propagation of scattered charged particles and control respective aperture angles.

Because the components of the system depicted in FIG. 6 are known generally, further description of them is not provided. In this embodiment, the CPB source 41, the illumination-lens assembly 42, the hollow-beam-forming aperture 45, and the first aperture stop 44 collectively constitute an “illumination-optical system” that is situated inside the column I (see, e.g., FIG. 2). The reticle 45 normally is mounted to a reticle stage (not shown) situated inside the reticle-stage chamber R. The projection-lens assembly 46 and the second aperture stop 47 collectively constitute a “projection-optical system” that is situated inside the column P. Inside the conveyor vacuum chamber 4, the substrate (wafer) 48 (denoted “5” in FIG. 2) is transported by the conveyor robot 7 to the wafer stage 8 inside the process vacuum chamber 3. The sensitive substrate 48 is exposed while placed on the wafer stage 8.

As discussed above, the chambers I, R, P usually are contiguous with the process vacuum chamber 3 (see, e.g., FIG. 1). With such a configuration, and according to the invention, transmission of vibrations from the conveyor robot 7 and from other vibration sources outside the process vacuum chamber 3 to the components, described above, that perform the actual microlithography of the substrate is attenuated. As a result, the present invention allows microlithographic exposures to be made even while substrates are being transported outside the process vacuum chamber 3.

Fifth Representative Embodiment

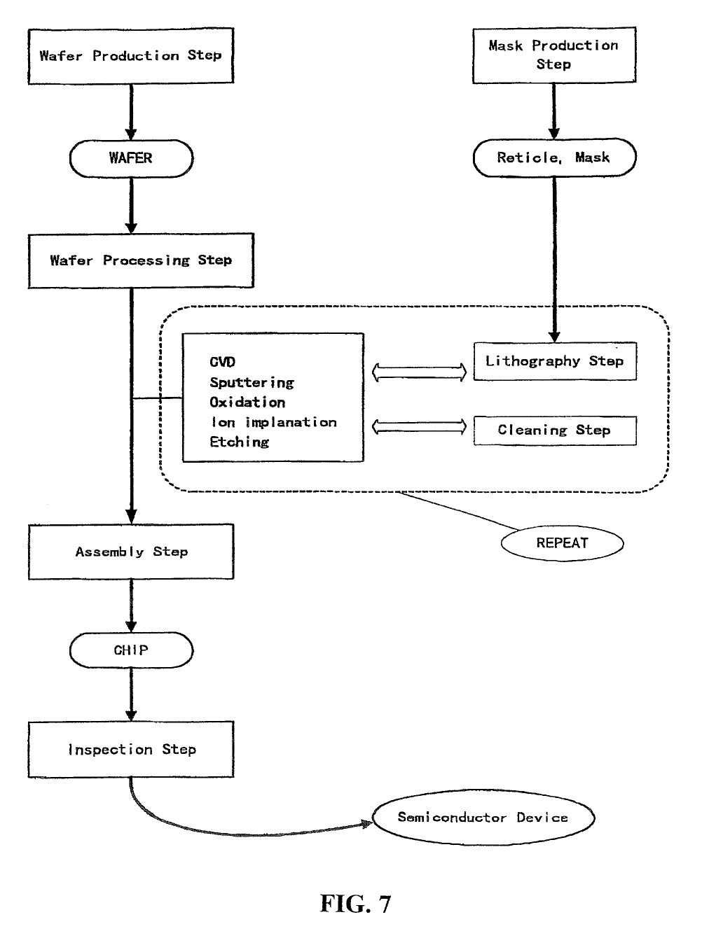

FIG. 7 is a flowchart of an exemplary microelectronic-fabrication method to which apparatus and methods according to the invention can be applied readily. The fabrication method generally comprises the main steps of wafer production (wafer preparation), wafer processing, device assembly, and device inspection. Each step usually comprises several sub-steps.

Among the main steps, wafer processing is key to achieving the smallest feature sizes (critical dimensions) and best inter-layer registration. In the wafer-processing step, multiple circuit patterns are layered successively atop one another on the wafer, forming multiple chips destined to be memory chips or main processing units (MPUs), for example. The formation of each layer typically involves multiple sub-steps. Usually, many operative microelectronic devices are produced on each wafer.

Typical wafer-processing steps include: (1) thin-film formation (by, e.g., sputtering or CVD) involving formation of a dielectric layer for electrical insulation or a metal layer for connecting wires or electrodes; (2) oxidation step to oxidize the substrate or the thin-film layer previously formed; (3) micro lithography to form a resist pattern for selective processing of the thin film or the substrate itself; (4) etching or analogous step (e.g., dry etching) to etch the thin film or substrate according to the resist pattern; (5) doping as required to implant ions or impurities into the thin film or substrate according to the resist pattern; (6) resist stripping to remove the remaining resist from the wafer; and (7) wafer inspection. Wafer processing is repeated as required (typically many times) to fabricate the desired semiconductor chips on the wafer.

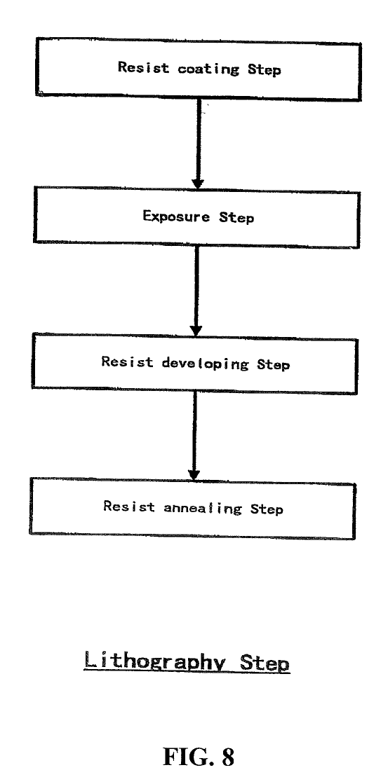

FIG. 8 provides a flow chart of typical steps performed in microlithography, which is a principal step in wafer processing. The microlithography step typically includes: (1) resist-application step, wherein a suitable resist is coated on the wafer substrate (which can include a circuit element formed in a previous wafer-processing step); (2) exposure step, to expose the resist with the desired pattern; (3) development step, to develop the exposed resist to produce the imprinted image; and (4) optional resist-annealing step, to enhance the durability of the resist pattern.

The process steps summarized above are all well known and are not described further herein.

Methods and apparatus according to the invention can be applied to a microelectronic-fabrication process, as summarized above, to provide substantially improved throughput. Throughput is improved principally by the ability, according to the invention, during microlithography to perform wafer exposure and wafer transport simultaneously in parallel rather than in series.

Whereas the invention has been described in connection with multiple representative embodiments, it will be understood that the invention is not limited to those embodiments. On the contrary, the invention is intended to encompass all alternatives, modifications, and equivalents as may be included within the spirit and scope of the invention, as defined by the appended claims.

What is claimed is:

1. In a processing apparatus including first and second vacuum chambers connected together by a pass-through flexible conduit, the conduit having an axis extending from the first vacuum chamber to the second vacuum chamber and being subjected to an axial compressive force whenever the vacuum chambers are evacuated relative to an environment surrounding the vacuum chambers, a device for reducing the axial compressive force, comprising:
a load-canceling device flanking the pass-through flexible conduit;
the load-canceling device comprising a first end connected to the first vacuum chamber and a second end connected to the second vacuum chamber; and
the load-canceling device being configured to apply a counter-force serving to offset and cancel at least a portion of the axial compressive force.

2. The device of claim 1, comprising multiple load-canceling devices flanking the pass-through flexible conduit.

3. The device of claim 2, comprising a first load-canceling device on a first axial side of the pass-through flexible conduit and a second load-canceling device on a second axial side, opposite the first axial side, of the pass-through flexible conduit.

4. The device of claim 1, wherein the load-canceling device is connected to the first vacuum chamber via a displacement absorber.

5. The device of claim 4, wherein the displacement absorber is configured to absorb pitch, roll, and yaw of the first vacuum chamber relative to the second vacuum chamber, as well as displacements of the first vacuum chamber relative to the second vacuum chamber in two dimensions perpendicular to the axis of the pass-through flexible conduit.

6. The device of claim 5, wherein the displacement absorber comprises:
a cross-roller table assembly attached to the first vacuum chamber;
a socket block attached to the cross-roller table assembly; and
a member having a first end configured as a spherical bearing journaled in the socket block, and a second end connected to the load-canceling device.

7. The device of claim 1, wherein the load-canceling device comprises a vacuum-bellows mechanism.

8. The device of claim 1, wherein the load-canceling device comprises an air spring.

9. The device of claim 8, wherein:
the air spring is connected to the first vacuum chamber via a displacement absorber; and
the displacement absorber is configured to absorb pitch, roll, and yaw of the first vacuum chamber relative to the second vacuum chamber, as well as displacements of the first vacuum chamber relative to the second vacuum chamber in two dimensions perpendicular to the axis of the pass-through flexible conduit.

10. The device of claim 7, wherein:
the vacuum-bellows mechanism comprises a vacuum bellows having a first end connected to the first vacuum chamber and a second end connected to the second vacuum chamber; and
the vacuum bellows is configured to generate the counter-force based on a pressure differential between a vacuum level established in at least one of the first and second vacuum chambers and the environment surrounding the first and second vacuum chambers.

11. The device of claim 10, wherein the vacuum bellows is connected via a conduit to at least one of the first and second vacuum chambers, the conduit providing a pressure in the vacuum bellows that is substantially equal to a pressure in the at least one vacuum chamber to which the conduit is connected.

12. The device of claim 10, wherein the vacuum-bellows mechanism further comprises:
a first support member connected to the first vacuum chamber and including a respective free end extending from the first vacuum chamber; and
a second support member connected to the second vacuum chamber and including a respective free end extending from the second vacuum chamber, wherein the vacuum bellows connects together the free ends of the first and second support members, the vacuum bellows being oriented so as to generate, whenever the first and second vacuum chambers are evacuated, an axial counter-force having a direction opposite the direction of the axial compressive force.

13. The device of claim 10, wherein:
the axial compressive force tends to move the first and second vacuum chambers together; and
the vacuum bellows generates a respective axial force tending to move the first and second vacuum chambers away from each other.

14. The device of claim 10, comprising first and second vacuum-bellows mechanisms flanking the pass-through flexible conduit and situated on respective opposite sides of the pass-through flexible conduit.

15. The device of claim 14, wherein:
the respective vacuum bellows of each vacuum-bellows mechanism defines a respective interior space; and
the respective interior spaces of the respective vacuum bellows are connected to a space defined by one of the vacuum chambers.

16. The device of claim 14, wherein each vacuum-bellows mechanism comprises:
a first respective bellows connected to the first vacuum chamber;
a respective chamber connected to the first respective bellows and to the second vacuum chamber, the respective chamber having an interior surface defining a respective interior space;
a second respective bellows connected to the interior surface and situated in the respective interior space; and
a piston plate located in the interior space and connected to the second respective bellows, wherein the first respective bellows is configured to provide a fluid connection from the first vacuum chamber to a space bounded by the interior surface, an inside surface of the second respective bellows, and the piston plate.

17. The device of claim 16, wherein the interior space defined by the respective chamber, an interior space defined by the first respective bellows, and an interior space defined by the second respective bellows are configured to be at a pressure that is substantially equal to a pressure in at least one of the vacuum chambers.

18. The device of claim 1, wherein at least one of the vacuum chambers is mounted to a rigid base via low-stiffness vibration isolators.

19. A vacuum-chamber assembly, comprising:
a first vacuum chamber;
a second vacuum chamber;
a pass-through flexible conduit connecting the first and second vacuum chambers together, the pass-through flexible conduit being subjected to an axial compressive force whenever the first and second vacuum chambers are evacuated relative to an environment surrounding the vacuum chambers; and
multiple load-canceling devices extending between the first and second vacuum chambers and flanking the pass-through flexible conduit such that the load-canceling devices are situated axially symmetrically relative to the pass-through flexible conduit, each load-canceling device being configured to apply a counter-force serving to offset a respective share of the axial compressive force.

20. The vacuum-chamber assembly of claim 19, comprising two load-canceling devices situated symmetrically on opposite sides of the pass-through flexible conduit.

21. The vacuum-chamber assembly of claim 19, wherein at least one of the first and second vacuum chambers is mounted to a rigid base via low-stiffness vibration isolators.

22. A process-chamber assembly, comprising:
a first process chamber;
a second process chamber;
a pass-through flexible conduit connecting the first and second process chambers together, the pass-through flexible conduit being subjected to an axial force tending to urge the process chambers axially apart or urge the process chambers together whenever the process chambers are pressurized or evacuated, respectively, relative to an environment external to the process chambers and pass-through flexible conduit; and
multiple load-canceling devices extending between the first and second process chambers and flanking the pass-through flexible conduit such that the load-canceling devices are situated axially symmetrically relative to the pass-through flexible conduit, each load-canceling device being configured to apply a counter-force serving to offset a respective share of the axial force.

23. The process-chamber assembly of claim 22, wherein each load-canceling member comprises a vacuum-bellows mechanism.

24. The process-chamber assembly of claim 23, wherein
the vacuum-bellows mechanism comprises a vacuum bellows having a first end connected to the first process chamber and a second end connected to the second process chamber; and
the vacuum bellows is configured to generate the counter-force based on a pressure differential between a pressure or vacuum level established in at least one of the first and second process chambers and the external environment.

25. The device of claim 24, wherein the vacuum bellows is connected via a conduit to at least one of the first and second process chambers, the conduit providing a pressure in the vacuum bellows that is substantially equal to a pressure in the at least one process chamber to which the conduit is connected.

26. The device of claim 24, wherein the vacuum-bellows mechanism further comprises:
a first support member connected to the first process chamber and including a respective free end extending from the first process chamber; and
a second support member connected to the second process chamber and including a respective free end extending from the second process chamber, wherein the vacuum bellows connects together the free ends of the first and second support members, the vacuum bellows being oriented so as to generate, whenever the first and second process chambers are pressurized or evacuated relative to the external environment, an axial counter-force having a direction opposite the direction of the axial force urging axial movement of the process chambers relative to each other.

27. The device of claim 24, wherein:
the respective vacuum bellows of each load-canceling device defines a respective interior space; and
the respective interior spaces of the respective vacuum bellows are connected to a space defined by one of the process chambers.

28. The device of claim 24, wherein each vacuum-bellows mechanism comprises:
a first respective bellows connected to the first process chamber;
a respective chamber connected to the first respective bellows and to the second process chamber, the respective chamber having an interior surface defining a respective interior space;
a second respective bellows connected to the interior surface and situated in the respective interior space; and
a piston plate located in the interior space and connected to the second respective bellows, wherein the first respective bellows is configured to provide a fluid connection from the first process chamber to a space bounded by the interior surface, an inside surface of the second respective bellows, and the piston plate.

29. The device of claim 28, wherein the interior space defined by the respective chamber, an interior space defined by the first respective bellows, and an interior space defined by the second respective bellows are configured to be at a pressure that is substantially equal to a pressure in at least one of the process chambers.

30. A microlithography apparatus, comprising:
an exposure-beam-optical column;
a first vacuum chamber including a first portion enclosing at least a portion of the exposure-beam column and a second portion enclosing a substrate stage;
a second vacuum chamber enclosing a conveyor for transporting substrates to and from the substrate stage;
a pass-through flexible conduit connecting together the first and second vacuum chambers; and
a load-canceling device flanking the pass-through flexible conduit, the load-canceling device comprising a first end connected to the first vacuum chamber and a second end connected to the second vacuum chamber, the load-canceling device being configured to apply a counter-force serving to offset and cancel at least a portion of the axial compressive force.

31. The microlithography apparatus of claim 30, wherein the exposure-beam column comprises an illumination-system column portion, a reticle-stage column portion, and a projection-system column portion.

32. A process for fabricating a microelectronic device, comprising the steps:
(a) preparing a wafer;
(b) processing the wafer; and
(c) assembling devices formed on the wafer during steps (a) and (b), wherein step (b) comprises the steps of (i) applying a resist to the wafer; (ii) exposing the resist; and (iii) developing the resist; and step (ii) comprises providing a microlithography apparatus as recited in claim 31; and using the microlithography apparatus to expose the resist with a pattern defined on a reticle.

33. A microelectronic device produced by the method of claim 32.
